(19) United States
(12) Patent Application Publication
(10) Pub. No.: US 2026/0129985 A1
(43) Pub. Date: May 7, 2026

(54) IMAGE SENSOR PIXEL CELL WITH MULTI-GATE TRANSFER TRANSISTOR

(71) Applicant: OMNIVISION TECHNOLOGIES, INC., Santa Clara, CA (US)

(72) Inventors: Duli Mao, Sunnyvale, CA (US); Yuanliang Liu, San Jose, CA (US); Bill Phan, Sunnyvale, CA (US); Woon Il Choi, Sunnyvale, CA (US); Po-Chun Chiu, Santa Clara, CA (US); Tomas Geurts, Parkstraat (BE)

(21) Appl. No.: 18/940,240

(22) Filed: Nov. 7, 2024

(51) Int. Cl. H01L 27/146

(52) U.S. Cl. CPC H10F 39/8023; H10F 39/18; H10F 39/80373; H10F 39/80377

(57) ABSTRACT

A pixel cell for an image sensor includes a first photodiode, a second photodiode, and a floating diffusion, each disposed within a semiconductor material. The pixel cell further includes a multi-gate transfer transistor configured to selectively couple the first photodiode and the second photodiode to the floating diffusion to transfer image charge from the first photodiode or the second photodiode to the floating diffusion. The multi-gate transfer transistor includes a plurality of separated gate electrodes including a first gate electrode disposed proximate to the first photodiode, a second gate electrode disposed proximate to the second photodiode, and a shared gate electrode disposed proximate to the floating diffusion. The multi-gate transfer transistor further includes an isolation structure disposed within the semiconductor substrate between the first photodiode and the second photodiode.

### TECHNICAL FIELD

This disclosure relates generally to image sensors, and in particular but not exclusively, relates to CMOS image sensors and applications thereof.

### BACKGROUND INFORMATION

Image sensors are one type of semiconductor device that have become ubiquitous and are now widely used in digital cameras, cellular phones, security cameras, as well as, medical, automobile, and other applications. As image sensors are integrated into a broader range of electronic devices it is desirable to enhance their functionality, performance metrics, and the like in as many ways as possible (e.g., resolution, power consumption, dynamic range, size, etc.) through both device architecture design as well as image acquisition processing. However, it is appreciated that many of these metrics are inversely related. For example, pixel size may be increased to improve dynamic range but have increased noise. In another example, resolution may be increased by increasing the number of pixels, but if pixel size is maintained then the physical size of the image sensor increases. Accordingly, improving one or more performance metrics of semiconductor devices such as image sensors while mitigating adverse effects on other performance metrics remains challenging.

The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bit lines that vary as a function of the incident image light. In other words, the amount of image charge generated is proportional to the intensity of the image light, which is readout as analog image signals from the column bit lines and converted to digital values to produce digital images (i.e., image data) representative of the external scene.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1A illustrates a plan view of a pixel cell included in an image sensor with a multi-gate transfer transistor, in accordance with an embodiment of the disclosure.

FIG. 1B illustrates a cross-sectional view along line W-W′ of the pixel cell in FIG. 1A, in accordance with an embodiment of the disclosure.

FIG. 1C illustrates a cross-sectional view along line Y-Y′ of the pixel cell in FIG. 1A, in accordance with an embodiment of the disclosure.

FIG. 1D illustrates a schematic for readout of the pixel cell in FIG. 1A, in accordance with an embodiment of the disclosure.

FIG. 1E illustrates a timing diagram for readout of the pixel cell in FIG. 1A operating in a low conversion gain mode and a high conversion gain mode, in accordance with embodiments of the disclosure.

FIG. 1F illustrates a potential diagram for the pixel cell of FIG. 1A operating in a low conversion gain mode and a high conversion gain mode, in accordance with embodiments of the disclosure.

FIG. 2A illustrates a plan view of a pixel cell included in an image sensor with two multi-gate transfer transistors, in accordance with an embodiment of the disclosure.

FIG. 2B illustrates a schematic for readout of the pixel cell in FIG. 2A, in accordance with an embodiment of the disclosure.

FIG. 2C illustrates a schematic for readout of the pixel cell in FIG. 2A when the pixel cell includes a dual conversion gain transistor, in accordance with an embodiment of the disclosure.

FIG. 2D illustrates a plan view of a pixel cell included in an image sensor with two multi-gate transfer transistors, in accordance with an embodiment of the disclosure.

FIG. 3 illustrates a process for operating a pixel cell including a multi-gate transfer transistor, in accordance with an embodiment of the disclosure.

FIG. 4 is a functional block diagram of an imaging system including a pixel cell with a multi-gate transfer transistor, in accordance with an embodiment of the disclosure.

### DETAILED DESCRIPTION

Embodiments of an apparatus, system, and method each related to a pixel cell of an image sensor pixel cell with a multi-gate transfer transistor are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

Conventional complementary metal-oxide semiconductor (CMOS) image sensors may utilize a shared pixel cell architecture in which multiple photodiodes share the same floating diffusion. However, conventional shared pixel cell architectures may result in a large floating diffusion area that may have higher junction capacitance and overlap capacitance that collectively result in lower conversion gain for the pixel cell. For example, in the case of four photodiodes sharing a common floating diffusion, at least four gate electrodes (e.g., transfer gates) may be directly coupled to and overlap with a floating diffusion to form a shared pixel cell architecture, which increases the overall capacitance of the floating diffusion due, at least in part, to overlap capacitances (e.g., caused by the four gate electrodes overlapping the floating diffusion or directly coupling to the floating diffusion) and increased area of the floating diffusion (e.g., to accommodate the four gate electrodes). However, the increased effective floating diffusion capacitance can lead to lower than optimal high conversion gain, which is associated with higher read noise and degraded low light performance of the pixel cell and/or image sensor.

Described herein are embodiments of a pixel cell for an image sensor and method of operation thereof with a multi-gate transfer transistor to provide high conversion gain. In embodiments of the disclosure, a multi-gate transfer transistor included in a pixel cell for an image sensor is configured to selectively couple multiple photodiodes to a floating diffusion to transfer photogenerated image charge to the floating diffusion (e.g., from a given photodiode included in the multiple photodiodes). In some embodiments, the multi-gate transfer transistor includes a plurality of separated gate electrodes such that multiple gate electrodes are disposed between the floating diffusion and a given photodiode included in the multiple photodiodes. Transfer of photogenerated image charge from the given photodiode to the floating diffusion may be achieved by simultaneously turning on the multiple gates disposed between the given photodiode and the floating diffusion. It is appreciated that the multiple gates included in the multi-gate transfer transistor include a shared gate electrode disposed proximate to the floating diffusion. In some embodiments, the shared gate electrode is further configured to be electrically disposed between unshared gate electrodes included in the multi-gate transfer transistor and corresponding photodiodes included in the multiple photodiodes. Advantageously, the multi-gate transfer transistor configuration enables reduced floating diffusion area (e.g., junction capacitance may be reduced by half compared to convention image sensors) and reduced overlap capacitance (e.g., since the shared gate electrode facilitates coupling to multiple photodiodes) to reduce the effective capacitance of the shared floating diffusion and lead to higher conversion gain for the pixel cell and/or image sensor. In some embodiments, the multi-gate transfer transistor may also be utilized to facilitate multiple conversion gain operation (e.g., a high conversion gain mode and a low conversion gain mode) of the pixel cell to improve dynamic range of the image sensor.

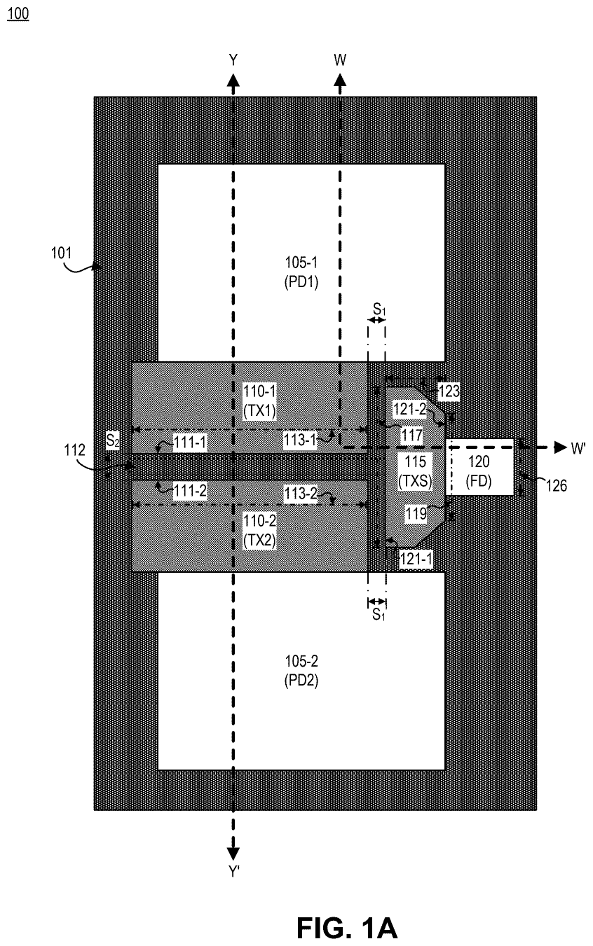

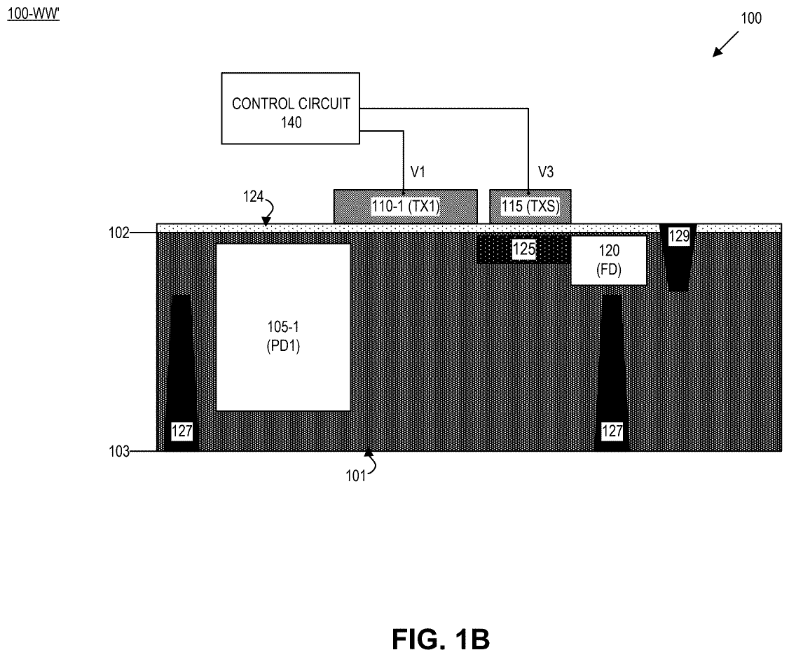

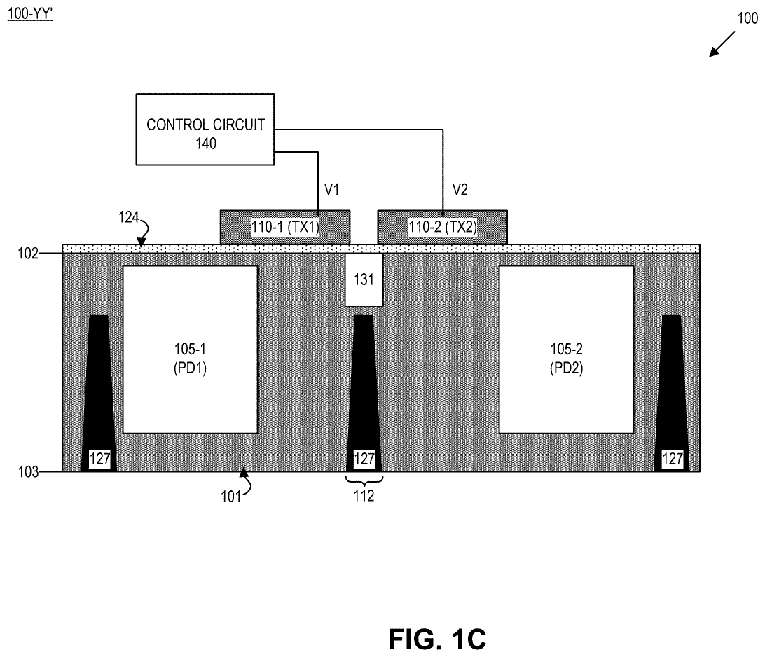

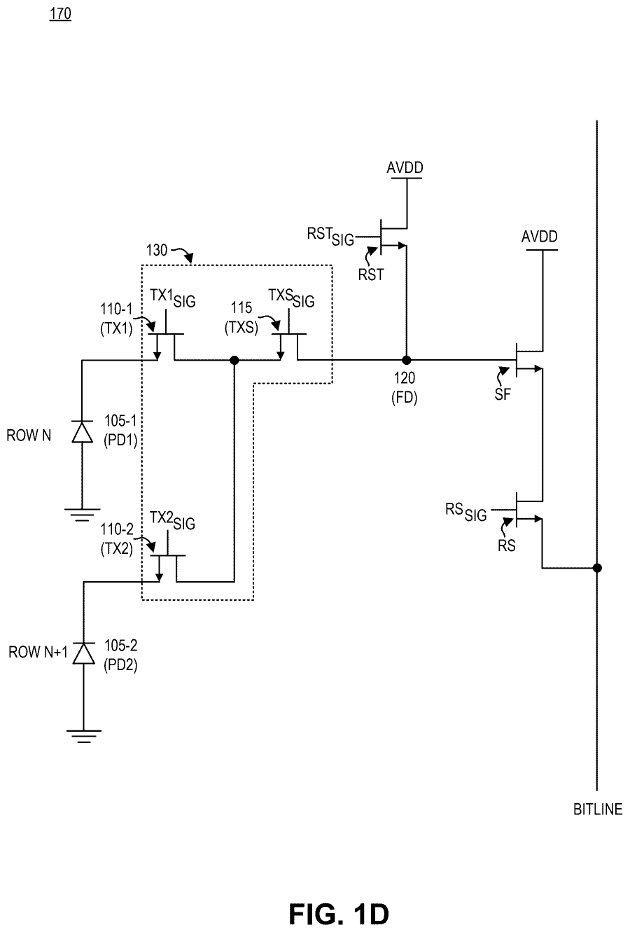

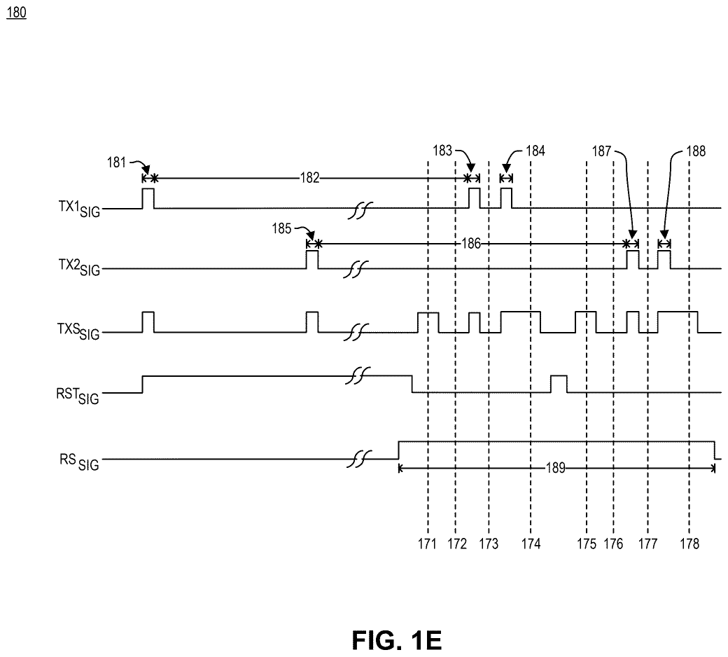

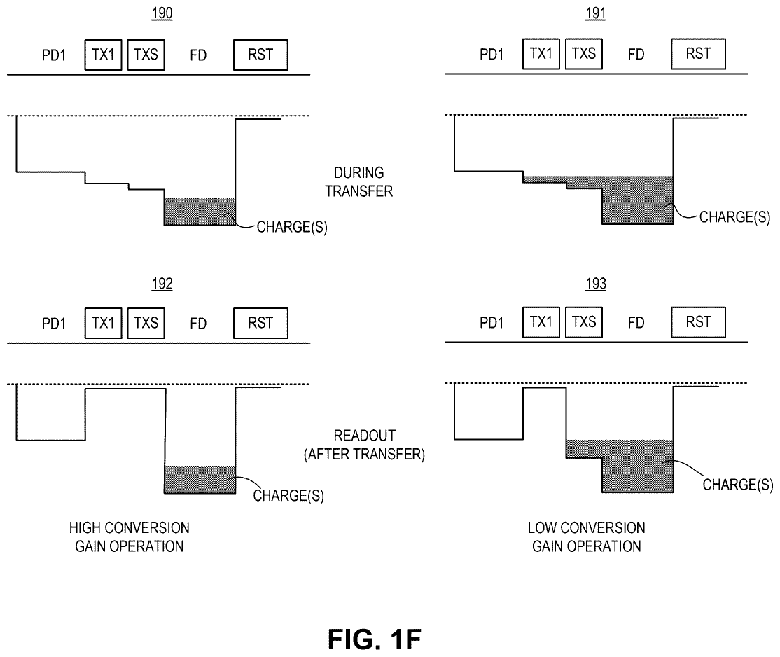

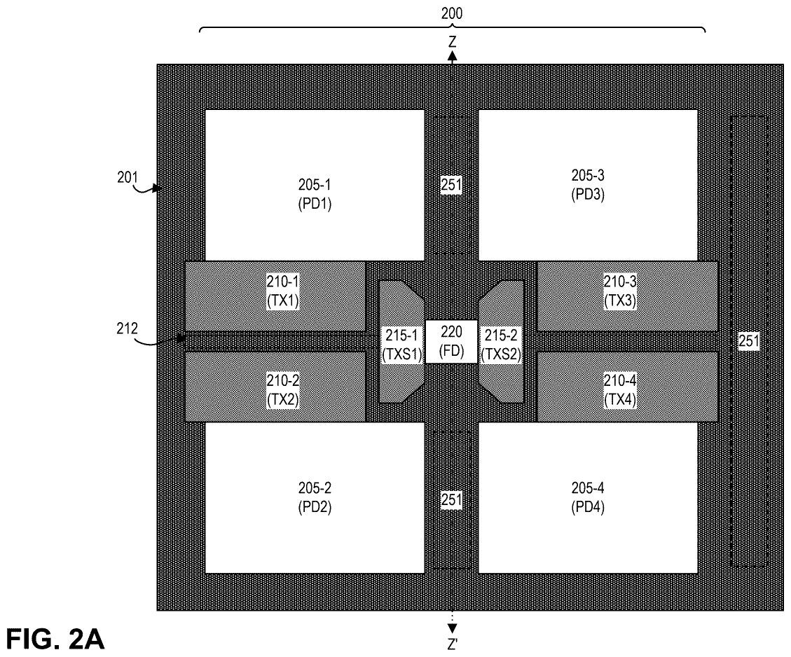

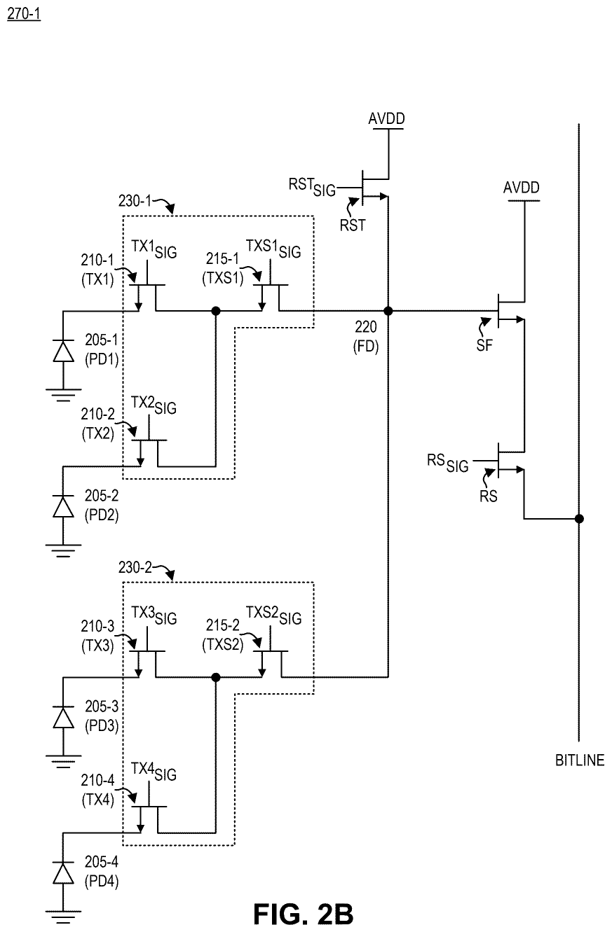

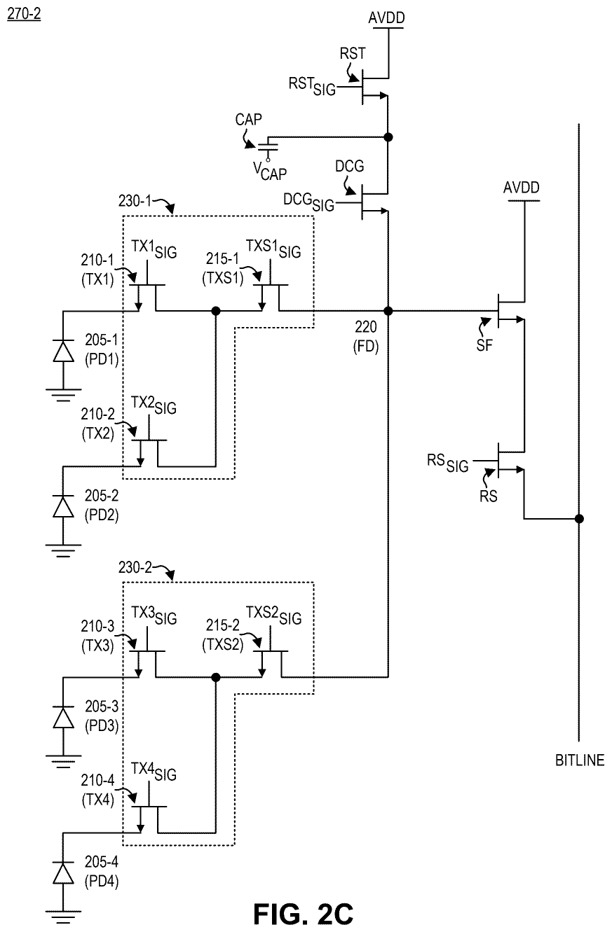

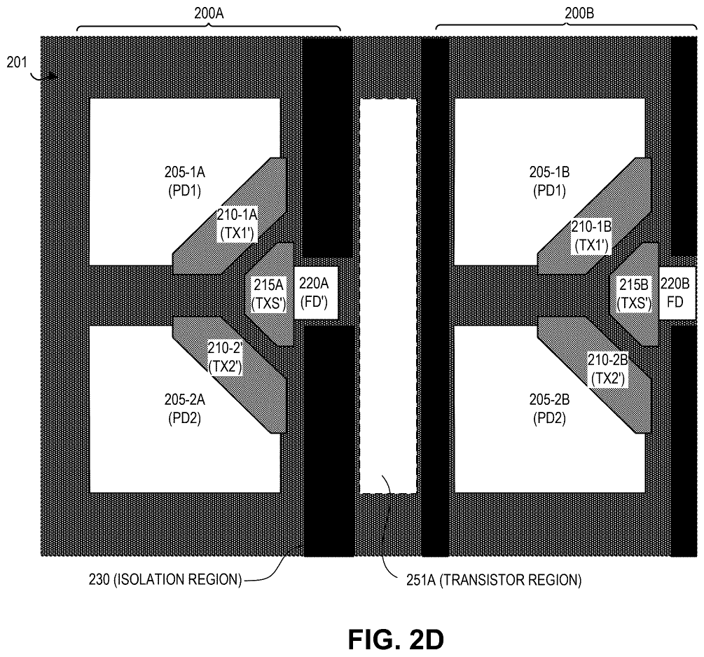

FIG. 1A illustrates a plan view of a pixel cell 100 included in an image sensor with a multi-gate transfer transistor, in accordance with an embodiment of the disclosure. Pixel cell 100 includes a semiconductor material 101, a first photodiode 105-1 (e.g., PD1), a second photodiode 105-2 (e.g., PD2), a first gate electrode 110-1 (e.g., TX1), a second gate electrode 110-2 (e.g., TX2), an isolation structure 112, a shared gate electrode 115 (e.g., TXS), and a floating diffusion 120 (e.g., FD). It is appreciated that the shape and arrangement of components included in pixel cell 100 (e.g., first gate electrode 110-1, second gate electrode 110-2, and shared gate electrode 115) is but one of many possible configuration in which a multi-gate transistor is utilized to selectively transfer image charge from adjacent photodiodes (e.g., first photodiode 105-1 and second photodiode 105-2) to a shared floating diffusion (e.g., floating diffusion 120) to enable improved conversion gain (e.g., for high conversion gain readout or operation). Accordingly, different configurations (see, e.g., FIG. 2D for another example embodiment) for an image sensor with a multi-gate transfer transistor may be utilized in accordance with embodiments of the disclosure. Thus, it is appreciated that other configurations not expressly illustrated may be utilized to form a pixel cell with a multi-gate transistor in accordance with embodiments of the disclosure.

In some embodiments, semiconductor material 101 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, semiconductor material 101 may correspond to any semiconductor material or combination of materials that may be doped or otherwise configured to facilitate the formation of an integrated circuit (e.g., individual circuitry components such as source/drain regions of transistors, memory elements, photodiodes, or the like). In one embodiment, semiconductor material 101 corresponds to an epitaxial layer (e.g., P-type silicon layer or N-type silicon layer). In such an embodiment, first photodiode 105-1, second photodiode 105-2, and/or any other photodiodes included in pixel cell 100 or the associated image sensor may be formed in the epitaxial layer corresponding to semiconductor material 101 while the carrier wafer may be removed or otherwise thinned during fabrication.

It is appreciated that the term “photodiode” (e.g., first photodiode 105-1, second photodiode 105-2, and/or other photodiodes included in pixel cell 100 or the associated image sensor) correspond to a doped region (e.g., via implantation) disposed within or otherwise surrounded by an oppositely doped region to form a photosensitive area capable of photogenerating image charge in response to incident light. For example, first photodiode 105-1 and/or second photodiode 105-2 may correspond to an N-type semiconductor (e.g., N-doped silicon) disposed within a P-type semiconductor material (e.g., P-type silicon corresponding to semiconductor material 101). Accordingly, in some embodiments first photodiode 105-1 and second photodiode 105-2 are oppositely doped (e.g., opposite conductivity type) relative to a doping type of semiconductor material 101. Floating diffusion 120 corresponds to a doped region (e.g., via implantation) disposed within semiconductor material 101. In some embodiments, first photodiode 105-1, second photodiode 105-2, and/or other photodiodes included in pixel cell 100 or the associated image sensor may correspond to a pinned photodiode, in which a P-N-P or N-P-N junction is formed where the central component of the junction corresponds to first photodiode 105-1, second photodiode 105-2, and so on (see, e.g., FIG. 1B).

In some embodiments, each of first photodiode 105-1, second photodiode 105-2, and/or other photodiodes included in pixel cell 100 may include a photodiode doped region, which is a part of semiconductor material that has been doped, for example by ion implantation, to have an opposite charge carrier type (i.e., conductivity type) relative to the majority charge carrier type of the semiconductor material such that an outer perimeter of the photodiode doped region forms a PN junction or a PIN junction of a respective photodiode. In such an embodiment, each of first photodiode 105-1, second photodiode 105-2, and/or other photodiodes included in pixel cell 100 may further include a pinning region (e.g., a doped region having a conductivity type opposite of the photodiode region conductivity type disposed between a surface of the semiconductor material and the photodiode doped region) to form a pinned photodiode. For example, the pinning region may have a P-type conductivity when the photodiode doped region is has N-type conductivity and the semiconductor substrate has P-type conductivity. In some embodiments, floating diffusion 120 has a same conductivity type (e.g., N-type) as corresponding photodiode doped regions included in first photodiode 105-1 and second photodiode 105-2, which in some embodiments is opposite of a conductivity type of semiconductor material 101 (e.g., P-type).

In some embodiments, first gate electrode 110-1, second gate electrode 110-2, and shared gate electrode 115 form a plurality of separated (e.g., distinct and physically separated) gate electrodes included in a multi-gate transfer transistor. Put in another way, individual gate electrodes (e.g., first gate electrode 110-1, second gate electrode 110-2, and shared gate electrode 115) included in the plurality of gate electrodes do not physically contact one another. For example, each of the plurality of gate electrodes may be disposed within or laterally surrounded by an insulating or dielectric material.

In some embodiments, first gate electrode 110-1, second gate electrode 110-2, and/or shared gate electrode 115 may include or otherwise correspond to a metal material (e.g., Au, Ag, Al, Cu, Ta, Ti, Nb, W, Mo), polycrystalline silicon (extrinsic or intrinsic), a silicide material, metal composites (e.g., WN, TiN, TaN, TiAl, TiAlC, other metal nitrides, RuOₓ, or other metal oxide electrode materials), other conductive materials with the appropriate conductivity and work function, or combinations thereof to facilitate image charge transfer.

More specifically, pixel cell 100 includes a multi-gate transfer transistor, including first gate electrode 110-1, second gate electrode 110-2, and shared gate electrode 115, configured to selectively couple first photodiode 105-1 and second photodiode 105-2 to floating diffusion 120 to selectively (e.g., based on voltages or signals applied to first gate electrode 110-1, second gate electrode 110-2, and shared gate electrode 115) transfer image charge from first photodiode 105-1 or second photodiode 105-2 to floating diffusion 120. In some embodiments, the first gate electrode 110-1 may be referred as a first transfer gate, second gate electrode 110-2 may be referred as a second transfer gate, and shared gate electrode 115 may be referred as a shared transfer gate. In other words, the multi-gate transfer transistor of pixel cell 100 includes at least two sources (e.g., photogenerated image charge respectively formed in or near first photodiode 105-1 and second photodiode 105-2) that may be independently accessed and a shared drain (e.g., floating diffusion 120). For example, shared gate electrode 115 and first gate electrode 110-1 may be turned on (e.g., applied voltage transitioned from a low level to a high level) during a readout period simultaneously to transfer image charge from first photodiode 105-1 to floating diffusion 120 (see, e.g., FIG. 1F) while second gate electrode 110-2 is turned off (e.g., applied voltage of a low level such as a negative voltage level). Subsequently, shared gate electrode 115 and second gate electrode 110-2 may be turned on (e.g., applied voltage transitioned from a low level to a high level) simultaneously to transfer image charge from second photodiode 105-2 to floating diffusion 120 (see, e.g., FIG. 1F) while the first gate electrode 110-1 is turned off (e.g., applied voltage of a low level such as a negative voltage level). In other words, the plurality of separated gate electrodes (e.g., first gate electrode 110-1, second gate electrode 110-2, and shared gate electrode 115) included in the multi-gate transfer transistor may be appropriately biased to form respective channels in the semiconductor material 101 extending from first photodiode 105-1 or second photodiode 105-2 to floating diffusion 120 (e.g., under shared gate electrode 115 and first gate electrode 110-1 or second gate electrode 110-2) to allow for selective and independent transfer of image charge to floating diffusion 120 from first photodiode 105-1 or second photodiode 105-2. It is appreciated the term “simultaneously” used herein or otherwise illustrated (see, e.g., FIG. 1E) when referring to operations (e.g., signal or voltage biasing to turn on or off transistors) are ideally simultaneous but may not necessarily be exactly simultaneous due to inherent or necessary circuitry delays in signal transmission (e.g., due to physical characteristics and/or tolerances of circuitry components) as known by one of ordinary skill in the art.

As illustrated, first gate electrode 110-1 is disposed proximate to first photodiode 105-1, second gate electrode 110-2 is disposed proximate to second photodiode 105-2, and shared gate electrode 115 is disposed proximate to floating diffusion 120. Shared gate electrode 115 is further disposed between floating diffusion 120 and both first gate electrode 110-1 and second gate electrode 110-2 when pixel cell 100 is viewed from a plan view (e.g., as illustrated in FIG. 1A). In the illustrated embodiment, shared gate electrode 115 tapers towards floating diffusion 120 when pixel cell 100 is viewed from the plan view of FIG. 1A to increase the separation distance between shared gate electrode 115 and adjacent photodiodes (i.e., first photodiode 105-1 and second photodiode 105-2) while increasing edge or face alignment between shared gate electrode 115 and both first gate electrode 110-1 and second gate electrode 110-2 to facilitate formation of a channel path extending from under first gate electrode 110-1 or second gate electrode 110-2 to under shared gate electrode 115 (e.g., between floating diffusion 120 and first photodiode 105-1 or second photodiode 105-2) during charge transfer.

In the illustrated embodiment, a first longitudinal edge 111-1 (e.g., a longest edge extending lengthwise along a first length 113-1) of first gate electrode 110-1 is parallel to a second longitudinal edge 111-2 (e.g., a longest edge extending lengthwise along a second length 113-2). In some embodiments, a third longitudinal edge 121-1 (e.g., longest edge extending lengthwise along a third length 117) of the shared gate electrode 115 is perpendicular to first longitudinal edge 111-1 of first gate electrode 110-1 and second longitudinal edge 111-2 of second gate electrode 110-2. In some embodiments, a fourth longitudinal edge 121-2 of shared gate electrode 115 is parallel to third longitudinal edge 121-1. In the same or other embodiments, fourth longitudinal edge 121-2 is smaller than third longitudinal edge 121-1 (e.g., third longitudinal edge 121-1 is a longest edge of shared gate electrode 115 while fourth longitudinal edge 121-2 is a second longest edge of shared gate electrode 115) such that shared gate electrode 115 tapers towards floating diffusion 120. For example, third length 117 of shared gate electrode 115 is greater than fourth length 119 of shared gate electrode 115.

In some embodiments, shared gate electrode 115 is disposed, at least in part, between first photodiode 105-1 and second photodiode 105-2 when pixel cell 100 is viewed from a plan view. In the illustrated embodiment, shared gate electrode 115 is disposed entirely between first photodiode 105-1 and second photodiode 105-2 when pixel cell 100 is viewed from the illustrated plan view of FIG. 1A. For example, an entirety of a width 123 of shared gate electrode 115 is disposed between first photodiode 105-1 and second photodiode 105-2 when pixel cell 100 is viewed from the plan view. In the same or other embodiments, fourth length 119 is greater than FD dimension 126 to reduce overlap capacitance between shared gate electrode 115 and floating diffusion 120.

In one embodiment, first length 113-1 of first gate electrode 110-1 is substantially equal (e.g., within 5%) of second length 113-2 of second gate electrode 110-2. In the same or other embodiments, first gate electrode 110-1 and second gate electrode 110-2 have a same shape different than a corresponding shape of shared gate electrode 115. As illustrated, first gate electrode 110-1 and second gate electrode 1110-2 are each disposed between first photodiode 105-1 and second photodiode 105-2 when pixel cell 100 is viewed from the plan view of FIG. 1A. It is appreciated that in some embodiments, first gate electrode 110-1 and second gate electrode 110-2 are positioned to be aligned lengthwise or otherwise overlap lengthwise with first photodiode 105-1 and second photodiode 105-2, respectively. In contrast, widths of first gate electrode 110-1 and second gate electrode 110-2 (e.g., dimension of first gate electrode 110-1 and second gate electrode 110-2 that is respectively perpendicular to first length 113-1 and second length 113-2) are aligned parallel to third length 117 of shared gate electrode 115. In the same or other embodiments, width 123 of shared gate electrode 115 is parallel to first length 113-1 of first gate electrode 110-1 and/or second length 113-2 of second gate electrode 110-2.

In some embodiments, shared gate electrode 115 at least partially overlaps (e.g., is disposed over) floating diffusion 120 but does not overlap first photodiode 105-1 nor second photodiode 105-2. In the illustrated embodiment, shared gate electrode 115 is distanced from each of first photodiode 105-1 and second photodiode 105-2. In the same embodiment, first gate electrode 110-1 at least partially overlaps (e.g., is disposed over) first photodiode 105-1 while second gate electrode 110-2 at least partially overlaps (e.g., is disposed over) second photodiode 105-2. In the same or other embodiments, a first separation distance S₁ between shared gate electrode 115 and first gate electrode 110-1 and/or second gate electrode 110-2 is smaller than a second separation distance S₂ between first gate electrode 110-1 and second gate electrode 110-2. In other words, in some embodiments, first gate electrode 110-1 and second gate electrode 110-2 are closer to shared gate electrode 115 than first gate electrode 110-1 and second gate electrode 110-2 are to each other.

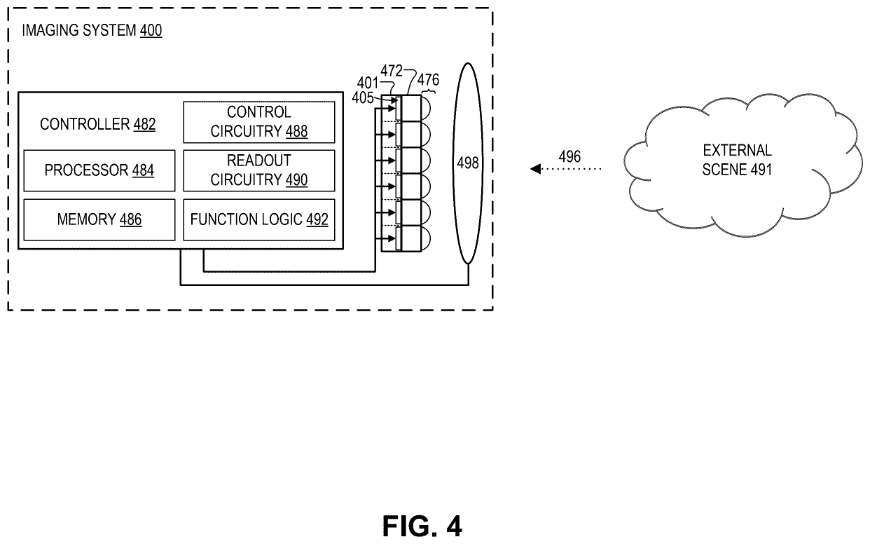

While not illustrated in FIG. 1A, in some embodiments, pixel cell 100 may be laterally surrounded by an isolation structure (e.g., a trench isolation structure such as a shallow trench isolation structure or a deep trench isolation structure, an isolation implant, and isolation well, or combinations thereof) disposed within semiconductor material 101 to isolate (e.g., electrically and/or optically) pixel cell 100 from adjacent pixel cells included in the image sensor. In other words, an image sensor including an array of instances of pixel cell 100 (see, e.g., FIG. 4) may have individual pixel cells isolated by the aforementioned isolation structure. Referring back to FIG. 1A, pixel cell 100 may also include an isolation structure 112 disposed within semiconductor material 101 to isolate first photodiode 105-1 from second photodiode 105-2 (e.g., to mitigate crosstalk between first photodiode 105-1 and second photodiode 105-2). In the illustrated embodiment, isolation structure 112 is further disposed between first gate electrode 110-1 and second gate electrode 110-2 when pixel cell 100 is viewed from the plan view illustrated in FIG. 1A. In some embodiments, isolation structure 112 includes a trench isolation structure such as a shallow trench isolation structure or a deep trench isolation structure, an isolation implant, an isolation well, or combinations thereof.

FIG. 1B illustrates a cross-sectional view 100-WW′ along line W-W′ of pixel cell 100 in FIG. 1A, in accordance with an embodiment of the disclosure. Cross-sectional view 100-WW′ shows a gate dielectric 124 disposed between semiconductor material 101 and each of the plurality of separated gate electrodes (e.g., first gate electrode 110-1 and shared gate electrode 115 illustrated in FIG. 1B and second gate electrode 110-2 illustrated in FIG. 1C) included in the multi-gate transfer transistor of pixel cell 100. Gate dielectric 124 provides electrical isolation between the plurality of separated gate electrodes and the “sources” (e.g., first photodiode 105-1 and second photodiode 105-2) and the shared drain (e.g., floating diffusion 120) of the multi-gate transfer transistor of pixel cell 100. In the illustrated embodiment, gate dielectric 124 corresponds to a continuous layer formed on a first side 102 (front side or non-illuminated side) of semiconductor material 101 that is opposite of a second side 103 (e.g., backside or illuminated side) of semiconductor material 101. However, it is appreciated that in other embodiments gate dielectric 124 may correspond to one or more distinct or separate regions (e.g., such that material composition, thickness, and/or capacitance provided may gate dielectric 124 may be tuned or adjusted for each one of first gate electrode 110-1, second gate electrode 110-2, shared gate electrode 115). In some embodiments, gate dielectric 124 includes one or more insulating materials (e.g., silicon dioxide, silicon oxynitride, hafnium dioxide, alumina oxide, zirconium oxide, or other gate dielectric materials known by one of ordinary skill in the art).

In one embodiment, pixel cell 100 includes an optional doped channel region 125 disposed within semiconductor material 101 proximate to (e.g., under) shared gate electrode 115. In the same or other embodiments, doped channel region 125 extends from floating diffusion 120 towards first photodiode 105-1 and/or second photodiode 105-2 (not illustrated in FIG. 1B). However, it is noted that in some embodiments doped channel region 125 is separate from (i.e., not in contact with) first photodiode 105-1 and second photodiode 105-2. In the same or other embodiments, gate dielectric 124 is disposed between doped channel region 125 and at least one of first photodiode 105-1 or second photodiode 105-2. In some embodiments, doped channel region 125 has a same dopant type or conductivity type relative to floating diffusion 120, first photodiode 105-1, and/or second photodiode 105-2 (e.g., N-type). In some embodiments, doped channel region 125 may have a doping concentration that is less than first photodiode 105-1, second photodiode 105-2, and/or floating diffusion 120. In one embodiment, a first doping concentration of the first photodiode 105-1 and/or second photodiode 105-2 is greater than a second doping concentration of the doped channel region 125 but less than a third doping concentration of floating diffusion 120. In some embodiments, a doping concentration of doped channel region 125 is one or two or three orders of magnitude less than a doping concentration of floating diffusion 120 to facilitate charge transfer from first photodiode 105-1 or second photodiode 105-2 to floating diffusion 120. In some embodiments, doped channel region 125 may have a doping concentration ranging from 1E17 ions/cm³ to 1E20 ions/cm³. In some embodiments, doped channel region 125 is disposed or otherwise formed proximate to first side 102 of semiconductor material 101 (e.g., to facilitate formation of a channel (e.g., when shared gate electrode 115 and at least one of first gate electrode 110-1 or second gate electrode 110-2 is turned on), proximate to first side 102, from first photodiode 105-1 or second photodiode 105-2 to floating diffusion 120. In such an embodiment, an implantation depth of dopants that form doped channel region 125 may be less than an implantation depth of floating diffusion 120, first photodiode 105-1, and/or second photodiode 105-2.

As illustrated in FIG. 1B, first photodiode 105-1 is isolated (e.g., from adjacent photodiodes included in pixel cells other than pixel cell 100) by deep trench isolation structure 127 while floating diffusion 120 is isolated from an adjacent floating diffusion (e.g., included in an adjacent pixel cell) by shallow trench isolation structure 129 and deep trench isolation structure 127. Deep trench isolation structure 127 and/or shallow trench isolation structure 129 may physically, electrically, and optically isolate components included in a given pixel cell (e.g., pixel cell 100) of a pixel cell array that forms, at least in part, an image sensor. In some embodiments, deep trench isolation structure 127 and/or shallow trench isolation structure 129 are formed by filling one or more trenches with one or more fill or liner materials (e.g., an insulating material such as silicon dioxide or other metal oxide material, polycrystalline silicon, a high-κ material with a dielectric constant greater than silicon dioxide such as HfOₓ, HfSiO, HfSiON, AlOₓ, or the like, or combinations thereof).

In some embodiments, plurality of separated gate electrodes (e.g., first gate electrode 110-1, second gate electrode 110-2, and shared gate electrode 115) are disposed proximate to front side 102 of semiconductor material 101. In the same or other embodiments, first gate electrode 110-1, second gate electrode 110-2, and shared gate electrode 115 are electrically isolated by a dielectric material (not illustrated). In some embodiments, the plurality of separated gate electrodes (e.g., first gate electrode 110-1, second gate electrode 110-2, and shared gate electrode 115) are individually coupled to receive a signal from a control circuit 140 such that electrodes included the plurality of separated gate electrodes are individually and separately addressable or otherwise configurable (e.g., to have an applied voltage V1, V2, or V3 corresponding to a low level voltage to turn “off” or a high level voltage to turn “on”). Control circuit 140 may be coupled to pixel cell 100 and other pixel cells included in the pixel cell array to control operation of pixel cell 100. Control circuit 140 may include logic to control operational characteristics of pixel cell 100 and other pixel cells included in the pixel cell array of the image sensor according to an operational state of pixel cell 100 (e.g., integration period, charge transfer period, high conversion read out mode, or low conversion readout mode, or other operational modes). Control circuit 140 may store instructions or otherwise be coupled to a non-transitory computer-readable storing the instructions that when executed by control circuit 140 causes pixel cell 100, the associated pixel cell array, and/or the associated image sensor to perform operations (e.g., to generate image signals and readout the image signals for generating an image representative of an external scene).

In some embodiments, one or more gate electrodes (e.g., first gate electrode 110-1, second gate electrode 110-2, and shared gate electrode 115) include a planar electrode portion and a vertical electrode portion extending from the planar electrode portion into semiconductor material 101. In one embodiment, each of first gate electrode 110-1 and second gate electrode 110-2 include a planar electrode portion and a vertical electrode portion extending from the planar electrode portion adjacent to respective first and second photodiodes 105-1, 105-2. In the same or other embodiments, shared gate electrode 115 includes a planar gate portion disposed proximate to front side 102 of semiconductor material 101.

FIG. 1C illustrates a cross-sectional view 100-YY′ along line Y-Y′ of pixel cell 100 in FIG. 1A, in accordance with an embodiment of the disclosure. As illustrated, gate dielectric 124 is disposed between first gate electrode 110-1 and semiconductor material 101. Gate dielectric 124 is further disposed between second gate electrode 110-2 and semiconductor material 101. First photodiode 105-1 and second photodiode 105-2 are isolated from adjacent photodiodes included in other pixel cells adjacent to pixel cell 100 by a trench isolation structure (e.g., deep trench isolation structure 127). In the same or other embodiments, the trench isolation structure may correspond to or include a shallow trench isolation structure. In some embodiments, an isolation implant or well may further provide isolation between photodiodes (e.g., first photodiode 105-1, second photodiode 105-2, etc.) included in pixel cell 100 and photodiodes included in pixel cells adjacent to pixel cell 100.

In the illustrated embodiment, isolation structure 112 provides isolation (e.g., electrical and/or optical isolation to mitigate crosstalk) between first photodiode 105-1 and second photodiode 105-2. As illustrated, isolation structure 112 includes a trench isolation structure (e.g., deep trench isolation structure 127) and isolation implant region 131 aligned with the trench isolation structure (e.g., isolation implant region 131 is aligned with the center one of deep trench isolation structure 127). It is appreciated that the term “aligned” indicates that isolation implant region 131 is disposed between first side 102 of semiconductor material 101 and the trench isolation structure (e.g., deep trench isolation structure 127), that the trench isolation structure (e.g., deep trench isolation structure 127) is disposed between second side 103 of semiconductor material 101 and isolation implant region 131, and/or that isolation implant region 131 is disposed between the trench isolation structure (e.g., deep trench isolation structure 127) and gate dielectric 124. In some embodiments, isolation implant region 131 is doped with an opposite dopant type relative to first photodiode 105-1 and second photodiode 105-2 (e.g., if first photodiode 105-1 and second photodiode 105-2 is N-doped or N-type conductivity then isolation implant region 131 is P-doped or P-type conductivity). In some embodiments a dopant concentration of isolation implant 131 is greater than a surrounding dopant concentration (e.g., of semiconductor material 101). In the same or other embodiments, isolation structure 112 may further include an isolation well. For example, in the illustrated embodiment, isolation implant region 131 extends from first side 102 of semiconductor material 101 towards deep trench isolation structure 127. However, in other embodiments, isolation implant region 131 may further extend towards second side 103 of semiconductor material 101 to encapsulate the aligned trench isolation structure (e.g., deep trench isolation structure 127).

It is appreciated when pixel cell 100 is viewed within the context of FIG. 1B and FIG. 1C, first gate electrode 110-1, second gate electrode 110-2, and/or shared gate electrode 115 extend along a common lateral plane (e.g., parallel to first side 102 or second side 103 of semiconductor material 101). It is further appreciated that in some embodiments, first gate electrode 110-1, second gate electrode 110-2, and shared gate electrode 115 may be isolated from one another by one or more encapsulating materials (silicon dioxide, a tetraethylorthosilicate, a high density plasma oxide material, other insulating materials, or combinations thereof) that form an intermetal dielectric layer disposed over and/or on first gate electrode 110-1, second gate electrode 110-2, and shared gate electrode 115.

It is further appreciated that in some embodiments, no junction (e.g., oppositely doped region relative to semiconductor material 101) is formed within semiconductor material 101 proximate to first side 102 and between shared gate electrode 115 and either of first gate electrode 110-1 or second gate electrode 110-2 when pixel cell 100 is viewed from a plan view. In such a manner, first photodiode 105-1 and second photodiode 105-2 may be isolated from floating diffusion 120 unless both of first gate electrode 110-1 and shared gate electrode 115 are configured by control circuit 140 to a high level voltage (e.g., turned on to transfer image charge from first photodiode 105-1 to floating diffusion 120) or unless both second gate electrode 110-2 and shared gate electrode 115 are configured by control circuit 140 to a high level voltage (e.g., turned on to transfer image charge form second photodiode 105-2 to floating diffusion 120). In such a manner, shared gate electrode 115 may be configured by control circuit 140 to selectively enable low conversion gain operation or readout and high conversion gain operation or readout of pixel cell 100 (see, e.g., FIG. 1E).

FIG. 1D illustrates a schematic 170 for readout of pixel cell 100 in FIG. 1A, in accordance with an embodiment of the disclosure. As illustrated schematic 170 for pixel cell 100 includes multi-gate transfer transistor 130, including first gate electrode 110-1, second gate electrode 110-2, and shared gate electrode 115, to selectively coupled first photodiode 105-1 disposed in row N of a pixel or photodiode array and second photodiode 105-2 disposed in row N+1 of the pixel or photodiode array to floating diffusion 120. Schematic 170 further includes a reset transistor including a reset gate RST configured to selectively reset floating diffusion 120, first photodiode 105-1, and/or second photodiode 105-2 to a reference voltage level (e.g., based on an analog supply voltage AVDD) upon receiving a reset signal, a source-follower transistor including a source-follower gate SF coupled to floating diffusion 120, a row select transistor including a row select gate RS coupled to selectively output an image signal to a bitline. It is appreciated that components of schematic 170 (e.g., multi-gate transfer transistor 130, floating diffusion 120, the reset transistor including reset gate RST, source-follower transistor including source-follower gate SF, the row select transistor including row select gate RS, and the bitline) may be included in readout circuitry associated with pixel cell 100 and/or the associated image cell.

Operation of schematic 170 may be controlled by control circuitry (e.g., control circuit 140 illustrated in FIG. 1B and FIG. 1C), which may apply various signals to turn on or off (e.g., configure to a high level voltage or a low level voltage) various transistors included in schematic 170. For example, control circuitry may control signals first transfer signal TX1_{SIG} applied to first gate electrode 110-1, second transfer signal TX2_{SIG} applied to second gate electrode 110-2, third (or shared) transfer signal TXS_{SIG} applied to shared gate electrode 115, reset signal RST_{SIG} applied to reset gate RST, and row select signal RS_{SIG} applied to row select gate RS (see, e.g., FIG. 1E). During operation, image charge photogenerated within or proximate to first photodiode 105-1 and/or second photodiode 105-2 may be selectively transferred to floating diffusion 120, which is applied to source-follower gate SF to turn “on” the source-follower transistor to generate an image signal that may be readout to the bitline. It is appreciated that the image signal is proportional to the amount of image charge transferred from first photodiode 105-1 or second photodiode 105-2 to floating diffusion 120 and is thus representative of an intensity of light of a given color (e.g., based on an overlying color filter) incident on first photodiode 105-1 and/or second photodiode 105-2.

It is appreciated that schematic 170 illustrates multi-gate transfer transistor 130 as including three transfer transistors. However, as discussed previously, in some embodiments there is no junction formed in semiconductor material 101 (e.g., there is not a source/drain region disposed within semiconductor material 101) between shared gate electrode 115 and either of first gate electrode 110-1 or second gate electrode 110-2. It is further appreciated that schematic 170 is an example of one possible implementation for readout of pixel cell 100. However, in other embodiments different configurations of readout circuitry may be utilized with multi-gate transfer transistor 130 (see, e.g., FIG. 2B or FIG. 2C, or other active pixel architectures known in the art such as 5T or 6T architectures).

FIG. 1E illustrates a timing diagram 180 for readout of pixel cell 100 in FIG. 1A operating in a low conversion gain mode and a high conversion gain mode, in accordance with embodiments of the disclosure. It is appreciated that while timing diagram 180 illustrates both low conversion gain mode operation and high conversion gain mode operation of pixel cell 100 to sequentially readout image signals associated with image charge photogenerated in or proximate to first photodiode 105-1 and/or second photodiode 105-2, in other embodiments operation may occur in one of low conversion gain mode or high conversion gain mode. It is further appreciated that timing diagram 180 is one example way to readout pixel cell 100, but in other embodiments pixel cell 100 may be readout in a different manner. Timing diagram 180 shows example signals (e.g., controlled by control circuitry such as control circuit 140 illustrated in FIGS. 1B and 1C) applied to gate electrodes included in readout circuitry for pixel cell 100 represented by schematic 170 illustrated in FIG. 1D (e.g., first transfer signal TX1_{SIG} applied to first gate electrode 110-1, second transfer signal TX2_{SIG} applied to second gate electrode 110-2, third (or shared) transfer signal TXS_{SIG} applied to shared gate electrode 115, reset signal RST_{SIG} applied to reset gate electrode RST, and RS_{SIG} applied to row select gate electrode RS). It is appreciated that collectively, first transfer signal TX1_{SIG}, second transfer signal TX2_{SIG}, and third (or shared) transfer signal TXS_{SIG} control operation of multi-gate transfer transistor 130.

The multi-gate transfer transistor 130 included in pixel cell 100 enables non-destructive dual-conversion-gain correlated-double-sampling readout for each photodiode (e.g., first photodiode 105-1, second photodiode 105-2, or any other photodiode included in the associated image sensor). In some embodiments, the high conversion gain mode may be used for low signal level sensing (e.g., low light environment conditions) and the low conversion gain mode may be used for high signal level sensing (e.g., normal or bright light environment conditions). In other words, the configuration of the multi-gate transfer transistor 130 enables increased dynamic range for pixel cell 100 and associated image sensor (e.g., by reducing read noise and improving low light performance enabled by the combination of the low conversion gain mode and high conversion gain mode). It is further appreciated that in some embodiments, readout circuitry included in or associated with pixel cell 100 may further include a separate dual-conversion-gain transistor and accompanying capacitor (see, e.g., FIG. 2C) to further reduce conversion gain (e.g., during the low conversion gain mode operation or as a separate mode of operation with further reduced conversion gain relative to the low conversion gain mode).

Referring back to FIG. 1E, time period 181 shows a pre-charge of first photodiode 105-1 by simultaneously configuring the signals (e.g., first transfer signal TX1_{SIG}, second transfer signal TXS_{SIG}, and reset signal RST_{SIG}) applied to first gate electrode 110-1, shared gate electrode 115, and reset gate RST to be at a high level voltage (e.g., an “on” state) to pre-charge first photodiode 105-1 to a pre-charge voltage. It is appreciated that in the illustrated embodiment, first transfer signal TX1_{SIG} and third (or shared) transfer signal TXS_{SIG} are simultaneously turned on (e.g., transitioned from the low level voltage to a high level voltage) and simultaneously turned off (e.g., transitioned from the high level voltage to the low level voltage) to initiate and terminate pre-charge of first photodiode 105-1. Time period 185 similarly shows a pre-charge of second photodiode 105-2 by simultaneously configuring the signals (e.g., second transfer signal TX2_{SIG}, third (or shared) transfer signal TXS_{SIG}, and reset signal RST_{SIG}) applied to second gate electrode 110-2, shared gate electrode 115, and reset gate RST to be at a high level voltage (e.g., an “on” state) to pre-charge second photodiode 105-2 to a pre-charge voltage. It is appreciated that in the illustrated embodiment, TX2_{SIG} and TXS_{SIG} are simultaneously turned on (e.g., transitioned from the low level voltage to a high level voltage) and simultaneously turned off (e.g., transitioned from the high level voltage to the low level voltage) to respectively initiate and terminate pre-charge of second photodiode 105-2.

Time period 182 illustrates a first integration period for accumulating or otherwise photogenerating image charge within or proximate to first photodiode 105-1 in response to incident light. Time period 186 illustrates a second integration period for accumulating or otherwise photogenerating image charge within or proximate to second photodiode 105-2 in response to incident light. Time period 189 illustrates a readout period to sample base voltage levels (e.g., SHR or reset level) and signal voltage levels (e.g., SHS) associated with first photodiode 105-1 and second photodiode 105-2 when pixel cell 100 is operating in a low conversion gain mode and/or a high conversion gain mode. More specifically, reference labels 171-178 correspond to examples of when to sample base voltage levels and signal voltage levels for generating image signals (e.g., corresponding to a difference between a pair of a sampled base voltage level and sampled signal voltage level). Time periods 183 and 184 illustrate first charge transfer periods for first photodiode 105-1 (e.g., to transfer image charge from or near first photodiode 105-1 to floating diffusion 120) respectively during a high conversion gain mode operation and a low conversion gain mode operation of pixel cell 100. Time periods 187 and 188 illustrate second charge transfer periods for second photodiode 105-2 (e.g., to transfer image charge from or near second photodiode 105-2 to floating diffusion 120) respectively during a high conversion gain mode operation and a low conversion gain mode operation of pixel cell 100. It is appreciated that the terms “high conversion gain mode operation” and “low conversion gain mode operation” of pixel cell 100 refer to readout operation modes of pixel cell 100.

During high conversion gain mode operation, a control circuit (e.g., control circuit 140 illustrated in FIGS. 1B and 1C) is configured to initiate a first charge transfer period (e.g., time period 183 for first photodiode 105-1) by simultaneously applying a first voltage (e.g., a high level voltage such as 2.8 V) to first gate electrode 110-1 and a second voltage (e.g., a high level voltage such as 3.2 or 3.3 V) to shared gate electrode 115 (e.g., first gate electrode 110-1 and shared gate electrode 115 are turned “on” simultaneously). During the first charge transfer period image charge is transferred from or near first photodiode 105-1 to floating diffusion 120. It is appreciated that in some embodiments, the high level voltages applied to separated gate electrodes (e.g., first gate electrode 110-1, second gate electrode 110-2, and/or shared gate electrode 115) included in the multi-gate transfer transistor 130 may be the same or different. It is further appreciated that in some embodiments, the low level voltages applied to separated gate electrodes (e.g., first gate electrode 110-1, second gate electrode 110-2, and/or shared gate electrode 115) included in the multi-gate transfer transistor 130 may be the same or different. In one embodiment, the first voltage and the second voltage (e.g., high level voltages applied to first gate electrode 110-1 and shared gate electrode 115) are each positive. In the same or other embodiments, the second voltage applied to shared gate electrode 115 is greater than the first voltage applied to first gate electrode 110-1 during the first charge transfer period (e.g., time period 183) to form a potential gradient to facilitate image charge transfer from first photodiode 105-1 to floating diffusion 120.

In some embodiments, the control circuit is further configured to terminate the first charge transfer period (e.g., time period 183) for the first photodiode 105-1 by transitioning the first voltage applied to first gate electrode 110-1 to a third voltage (e.g., a low level voltage such as ground reference voltage or negative voltage e.g., −1.4 V) and further transitioning the second voltage applied to the shared gate electrode 115 to a fourth voltage (e.g., a low level voltage such as from −1 V to 0 V). In some embodiments, the transitioning the first voltage applied to first gate electrode 110-1 to the third voltage and the transitioning the second voltage applied to the shared gate electrode 115 to the fourth voltage (e.g., turning “off” the signal applied to first gate electrode 110-1 and shared gate electrode 115) occurs simultaneously. In other embodiments, the transitioning the second voltage applied to the shared gate electrode 115 to the fourth voltage occurs after the transitioning the first voltage applied to first gate electrode 110-1 to the third voltage (e.g., first gate electrode 110-1 is turned “off” before shared gate electrode 115 is turned “off” based on a small sub-microsecond timing delay needed for on-off transition) to reduce charge spill-back. In some embodiments, the third voltage and the fourth voltage (e.g., low level voltages applied to first gate electrode 110-1 and shared gate electrode 115) are each negative. In some embodiments, the fourth voltage applied to shared gate electrode 115 is zero. In the same or other embodiments, the fourth voltage applied to shared gate electrode 115 is greater than the third voltage applied to first gate electrode 110-1 to reduce gate-induced drain leakage to floating diffusion 120. It is appreciated that the second charge transfer period to transfer image charge from second photodiode 105-2 to floating diffusion 120 during a high conversion gain mode operation may similarly be initiated and terminated (see, e.g., time period 187).

It is appreciated that in general, pixel cell 100 or the associated image sensor comprises a control circuit (e.g., control circuit 140 illustrated in FIGS. 1B and 1C) to configure a voltage level (e.g., a high level voltage or a low level voltage respectively corresponding to an “on” state and an “off state) applied to shared gate electrode 115 during a high conversion gain operation and a low conversion gain operation. During the high conversion gain operation, the voltage level applied to shared gate electrode 115 of multi-gate transfer transistor is a low level (e.g., “off” state) and during the low conversion gain readout operation, the voltage level applied to shared gate electrode 115 of multi-gate transfer transistor is a high level (e.g., “on” state). For example, charge transfer during a high conversion gain mode operation (see, e.g., time period 183), is terminated by turning “off” first gate electrode 110-1 and shared gate electrode 115 (e.g., third or (shared) transfer signal TXS_{SIG} and first transfer signal TX1_{SIG} are transitioned from a high level voltage to a low level voltage while second transfer signal TX2_{SIG} continues to remain at the low level voltage) such that during high conversion gain sampling for the signal level voltage (see, e.g., reference label 173) occurs when first gate electrode 110-1, second gate electrode 110-2, and shared gate electrode 115 are each off (e.g., based on third (or shared) transfer signal TXS_{SIG}, first transfer signal TX1_{SIG}, and second transfer signal TX2_{SIG} each configured to the low level voltage). In contrast, charge transfer during a low conversion gain mode operation (see, e.g., time period 184), is terminated by turning “off” first gate electrode 110-1 but leaving shared gate electrode 115 “on” (e.g., first transfer signal TX1_{SIG} is transitioned from the high level voltage to the low level voltage, third or shared transfer signal TXS_{SIG} continues to remain at the high level voltage, and second transfer signal TX2_{SIG} continues to remain at the low level voltage) such that during low conversion gain sampling for the signal level voltage (see, e.g., reference label 174) occurs when first gate electrode 110-1 and second gate electrode 110-2 are each “off”, but shared gate electrode 115 is “on” (e.g., based on TX1_{SIG} and TX2_{SIG} each configured to the low level voltage and TXS_{SIG} configured to the high level voltage).

In other words, shared gate electrode 115 of multi-gate transfer transistor 130 is configured to modulate conversion gain of pixel cell 100 during readout (e.g., depending high or low conversion gain mode) by adjusting coupling capacitance between shared gate electrode 115 and floating diffusion 120 while the physical separation between shared gate electrode 115 and first gate electrode 110-1 and second gate electrode 110-2 provides isolation between floating diffusion 120 and both first photodiode 105-1 and second photodiode 105-2. For example, even if shared gate electrode 115 is turned “on” during low conversion gain readout operation, first gate electrode 110-1 and a second gate electrode 110-2 are turned “off” such that floating diffusion 120 is isolated from first photodiode 105-1 and second photodiode 105-2, which advantageously results in image charge photogenerated by each of photodiode 105-1 and second photodiode 105-2 from affecting low conversion gain operation (e.g., during low conversion gain operation, photodiodes 105-1 and/or 105-2 may still photogenerate image charge in response to incident light, but said image charge is prevented by the configuration of the multi-gate transfer transistor from affecting low conversion gain operation).

In the illustrated embodiment, reference labels 171 and 175 respectively show when to sample a base or reference voltage level (e.g., SHR) for first photodiode 105-1 or second photodiode 105-2 during low conversion gain mode operation (e.g., third or shared transfer signal TXS_{SIG} is configured to a high level voltage while first transfer signal TX1_{SIG} and second transfer signal TX2_{SIG} are configured to a low level voltage after integration). Reference labels 172 and 176 respectively show when to sample a base or reference voltage level (e.g., SHR) for first photodiode 105-1 or second photodiode 105-2 during high conversion gain mode operation (e.g., third or shared transfer signal TXS_{SIG}, first transfer signal TX1_{SIG}, and second transfer signal TX2_{SIG} are configured to a low level voltage after integration). Reference labels 173 and 177 respectively show when to sample a signal voltage level (e.g., SHS) for first photodiode 105-1 or second photodiode 105-2 during high conversion gain mode operation (e.g., third or shared transfer signal TXS_{SIG}, first transfer signal TX1_{SIG}, and second transfer signal TX2_{SIG} are configured to a low level voltage after charge transfer represented by time period 183 or 187). Reference labels 174 and 178 respectively show when to sample a signal voltage level (e.g., SHS) for first photodiode 105-1 or second photodiode 105-2 during low conversion gain mode operation (e.g., third or shared transfer signal TXS_{SIG} is configured to a high level voltage while first transfer signal TX1_{SIG} and second transfer signal TX2_{SIG} are configured to a low level voltage after charge transfer represented by time period 184 or 188).

FIG. 1F illustrates a potential diagram for pixel cell 100 of FIG. 1A operating in a low conversion gain mode and a high conversion gain mode, in accordance with embodiments of the disclosure. In particular, during a charge transfer period (e.g., time period 183 or 184 illustrated in FIG. 1E), image charge is transferred from PD1 (e.g., first photodiode 105-1) to floating diffusion FD (e.g., floating diffusion 120) as illustrated by diagrams 190 and 191. During high conversion gain operation as illustrated by diagram 192 (see, e.g., reference label 173 of FIG. 1E), image charge is confined to floating diffusion FD (e.g., since TX1 corresponding to first gate electrode 110-1, TXS corresponding to shared gate electrode 115, and RST corresponding to reset gate RST are each “off”) for readout. As such, image charge for high conversion gain readout operation is read based on the junction capacitance of floating diffusion FD. In contrast, during low conversion gain operation as illustrated by diagram 193 (see, e.g., reference label 174 of FIG. 1E), image charge is confined to storage associated with shared gate electrode TXS (e.g., corresponding to shared gate electrode 115) and floating diffusion FD (e.g., since TX1 corresponding to first gate electrode 110-1 and RST corresponding to reset gate RST are each “off” while TXS corresponding to shared gate electrode 115 is “on”). As such, image charge for low conversion gain readout operation is read based on a combination of junction capacitance of floating diffusion FD and MOS capacitance of shared transfer gate TXS.

FIG. 2A illustrates a plan view of a pixel cell 200 included in an image sensor with two multi-gate transfer transistors, in accordance with an embodiment of the disclosure. Pixel cell 200 includes a semiconductor material 201, a first photodiode 205-1 (e.g., PD1), a second photodiode 205-2 (e.g., PD2), a third photodiode 205-3 (e.g., PD3), a fourth photodiode 205-4, (e.g., PD4), a first gate electrode 210-1 (e.g., TX1), a second gate electrode 210-2 (e.g., TX2), a third gate electrode 210-3 (e.g., TX3), a fourth gate electrode 210-4 (e.g., TX4), an isolation structure 212, a first shared gate electrode 215-1 (e.g., TXS1), a second shared gate electrode 215-2 (e.g., TXS2), a floating diffusion 220 (e.g., FD), and regions for circuitry 251 to be formed in or on semiconductor material 201. In some embodiments, pixel cell 200 represents pixel cell 100 illustrated in FIG. 1A-1F reconfigured from a two-by-one photodiode per pixel cell array to a two-by-two photodiode per pixel cell. Put in another way, in some embodiments pixel cell 200 corresponds to pixel cell 100 mirrored about axis ZZ′ such that there are two multi-gate transfer transistors that collectively and selectively coupled four photodiodes (e.g., first photodiode 205-1, second photodiode 205-2, third photodiode 205-3, and fourth photodiode 205-4) to floating diffusion 220 via two shared gate electrodes (e.g., first shared gate electrode 215-1 and second shared gate electrode 215-2). Accordingly, it is appreciated that like-labeled elements may have a similar composition, configuration, effect, and the like (e.g., first photodiode 205-1, second photodiode 205-2, third photodiode 205-3, and fourth photodiode 205-4 of FIG. 2A may be analogous to first photodiode 105-1 and second photodiode 105-2 of FIG. 1A-1F), in accordance with embodiments of the disclosure.

As illustrated, first photodiode 205-1, second photodiode 205-2, third photodiode 205-3, and fourth photodiode 205-4 are each disposed within semiconductor material 201. First gate electrode 210-1, second gate electrode 210-2, and first shared gate electrode 215-1 form a first multi-gate transfer transistor configured to selectively couple first photodiode 205-1 and second photodiode 205-2 to floating diffusion 220 to transfer image charge from first photodiode 205-1 or second photodiode 205-2 to floating diffusion 220. In some embodiments, first gate electrode 210-1, second gate electrode 210-2, and shared gate electrode 215-1 may be referred to as a plurality of first separated gate electrodes where first gate electrode 210-1 is disposed proximate to first photodiode 205-1, second gate electrode 210-2 is disposed proximate to second photodiode 205-2, and first shared gate electrode 215-1 is disposed proximate to floating diffusion 220. In the same embodiment, third gate electrode 210-3, fourth gate electrode 210-4, and second shared gate electrode 215-1 form a second multi-gate transfer transistor configured to selectively couple third photodiode 205-3 and fourth photodiode 205-4 to floating diffusion 220 to transfer image charge from third photodiode 205-3 or fourth photodiode 205-4 to floating diffusion 220. In some embodiments, third gate electrode 210-3, fourth gate electrode 210-4, and second shared gate electrode 215-2 may be referred to as a plurality of second separated gate electrodes where third gate electrode 210-3 is disposed proximate to third photodiode 205-3, fourth gate electrode 210-4 is disposed proximate to fourth photodiode 205-4, and second shared gate electrode 215-2 is disposed proximate to floating diffusion 220.

In some embodiments, floating diffusion 220 is disposed between first shared gate electrode 215-1 and second shared gate electrode 215-2 when pixel cell 200 is viewed from a plan view (e.g., as illustrated in FIG. 2A). In the same or other embodiments, first shared gate electrode 215-1 and second shared gate electrode 215-2 are each disposed between first gate electrode 210-1 and third gate electrode 210-3. In the same or other embodiments, first shared gate electrode 215-1 and second shared gate electrode 215-2 are further disposed between second gate electrode 210-2 and fourth shared gate electrode 210-4. In the same or other embodiments, first gate electrode 210-1, second gate electrode 210-2, third gate electrode 210-3, fourth gate electrode 210-4, first shared gate electrode 215-1, and second shared gate electrode 215-2 each extend along a common or same lateral plane. In the same or other embodiments, first shared gate electrode 215-1 and second shared gate electrode 215-2 each taper toward floating diffusion 220 when pixel cell 200 is viewed from the plan view illustrated in FIG. 2A.

FIG. 2B illustrates a schematic 270-1 for readout of pixel cell 200 in FIG. 2A, in accordance with an embodiment of the disclosure. Schematic 270-1 is similar in many regards to schematic 170 illustrated in FIG. 1D and thus for the sake of brevity, descriptions of certain components (e.g., reset gate RST, source-follower gate SF, row select gate RS, etc.) and operations will not be elaborated as one having the benefit of the disclosure will understand how operation of pixel cell 200 may similarly be controlled in reference to FIG. 1A-1F. One difference is schematic 270-1 shows two multi-gate transfer transistors (e.g., first multi-gate transfer transistor 230-1 including first gate electrode 110-1, second gate electrode 210-2, and first shared gate electrode 115-1 and second multi-gate transfer transistor 230-2 including third gate electrode 210-3, fourth gate electrode 210-4, and second shared gate electrode 215-2) that respectively and selectively couple first photodiode 205-1, second photodiode 205-2, third photodiode 205-3, and fourth photodiode 205-4 to floating diffusion 220. It is appreciated that each of the separated gate electrodes included in first multi-gate transfer transistor 230-1 and second multi-gate transfer transistor 230-2 may be controlled by a respective signal applied thereof (e.g., TX1_{SIG} applied to first gate electrode 210-1, TX2_{SIG} applied to second gate electrode 210-2, TX3_{SIG} applied to third gate electrode 210-3, TX4_{SIG} applied to fourth gate electrode, TXS1_{SIG} applied first shared gate electrode 215-1, and TXS2_{SIG} applied to second shared gate electrode 215-2).

FIG. 2C illustrates a schematic 270-2 for readout of pixel cell 200 in FIG. 2A when pixel cell 200 includes a dual conversion gain transistor, in accordance with an embodiment of the disclosure. Schematic 270-2 is similar in many regards to schematic 270-1 illustrated in FIG. 2B and schematic 170 illustrated in FIG. 1D and thus for the sake of brevity, descriptions of certain components (e.g., first multi-gate transfer transistor 230-1, second multi-gate transfer transistor 230-2, reset gate RST, source-follower gate SF, row select gate RS, etc.) and operations will not be elaborated as one having the benefit of the disclosure will understand how operation of pixel cell 200 may similarly be controlled in reference to FIG. 1A-2B. One difference is schematic 270-2 illustrated in FIG. 2C further includes a dual conversion gain transistor coupled in series between a capacitor CAP and floating diffusion FD 220. The illustrated dual conversion gain transistor includes a dual conversion gate electrode DCG configurable by a dual conversion gain signal DCG_{SIG} (e.g., operable by a control circuit such as control circuit 140 illustrated in FIG. 1B-1C) for modulating a conversion gain of pixel cell 200. The capacitor CAP may be coupled to a reference voltage (e.g., V_{CAP}). It is appreciated that during low conversion gain operation, dual conversion gain signal DCG_{SIG} may be configured to a high level voltage to further reduce the conversion gain (e.g., such that during readout dual conversion gain gate DCG and first shared gate electrode 215-1 or second shared gate electrode 215-2 are both “on”).

FIG. 2D illustrates a plan view of pixel cells 200A, 200B included in an image sensor with two multi-gate transfer transistors, in accordance with an embodiment of the disclosure. Pixel cell 200A includes a semiconductor material 201, a first photodiode 205-1A (e.g., PD1), a second photodiode 205-2A (e.g., PD2), a first gate electrode 210-1A (e.g., TX1′), a second gate electrode 210-2A (e.g., TX2′), an isolation structure 230, a shared gate electrode 215A (e.g., TXS′), a floating diffusion 220A (e.g., FD′), and regions for circuitry 251A to be formed in or on semiconductor material 201. Pixel cell 200B is adjacent to pixel cell 200A and may include the same or similar components. In other words, pixel cell 200B corresponds to another instance of pixel cell 200A and includes the same elements suffixed with a “B” instead of an “A”. For example, pixel cell 200B includes a first photodiode 205-1B (e.g., PD1), a second photodiode 205-2B (e.g., PD2), a first gate electrode 210-1B (e.g., TX1′), a second gate electrode 210-2B (e.g., TX2′), an isolation structure 230, a shared gate electrode 215B (e.g., TXS′), a floating diffusion 220B (e.g., FD′).

In some embodiments, pixel cell 200A and/or pixel cell 200B provide another configuration representation for pixel cell 100 illustrated in FIG. 1A-1F. Accordingly, it is appreciated that like-labeled or named elements may have similar composition, properties, functionality, and the like (e.g., first photodiode 205-1 illustrated in FIG. 2B may be comparable to first photodiode 105-1 illustrated in FIG. 1A-1F, floating diffusion 220′ illustrated in FIG. 2B may be comparable to floating diffusion 120 illustrated in FIG. 1A-1F, and so on).

As illustrated, first photodiode 205-1A and second photodiode 205-2A are each disposed within semiconductor material 201. First gate electrode 210-1A, second gate electrode 210-2A, and shared gate electrode 215A form a multi-gate transfer transistor configured to selectively couple first photodiode 205-1A and second photodiode 205-2A to floating diffusion 220A to transfer image charge from first photodiode 205-1A or second photodiode 205-2A to floating diffusion 220A. In some embodiments, first gate electrode 210-1A is disposed proximate to first photodiode 205-1A, second gate electrode 210-2A is disposed proximate to second photodiode 205-2A, and shared gate electrode 215A is disposed proximate to floating diffusion 220A. In some embodiments, shared gate electrode 215A tapers away from floating diffusion 220A.

In some embodiments, floating diffusion 220A is disposed between shared gate electrode 215A and a transistor region containing circuitry 251A when pixel cell 200A is viewed from a plan view. In the same or other embodiments, the transistor region containing circuitry 251A is disposed between pixel cell 200A and adjacent pixel cell 200B and circuitry 251A is coupled to first photodiode 205-1, second photodiode 205-2, and floating diffusion 220′ of pixel cell 200A for reset and image signal readout operations. In some embodiments, circuitry 251A may include a source-follower transistor, a reset transistor, a row select transistor, a dual floating diffusion transistor, and the like). In some embodiments, floating diffusion 220A is disposed between shared gate electrode 215A and circuitry 251A.

In the same or other embodiments, shared gate electrode 215A is disposed between first gate electrode 210-1′ (e.g., TX1′) and second gate electrode 210-2′ (e.g., TX2′). In the illustrated configuration, first gate electrode 210-1′ (e.g., TX1′) and second gate electrode 210-2′ (e.g., TX2′) are disposed to define a space region on the semiconductor material 201, and shared gate electrode 215A is disposed in that space region enabling pixel cell 200A be compactly designed. In the illustrated embodiment, first gate electrode 210-1A and second gate electrode 210-2A at least partially enclose or otherwise define a space or region for shared gate electrode 215A. For example, at least two sides of shared gate electrode 215A face, collectively, first transfer gate electrode 210-1A and second transfer gate electrode 210-2A.

Isolation region 230 is disposed in or on semiconductor material 201 to provide isolation between each of first photodiode 205-1 and second photodiode 205-2 from circuitry 251A. Isolation region 230 may include a trench isolation structure and/or a doped region having an opposite conductive type as floating diffusion 220′ or photodiode doped region of each of photodiode 205-1 and second photodiode 205-2.

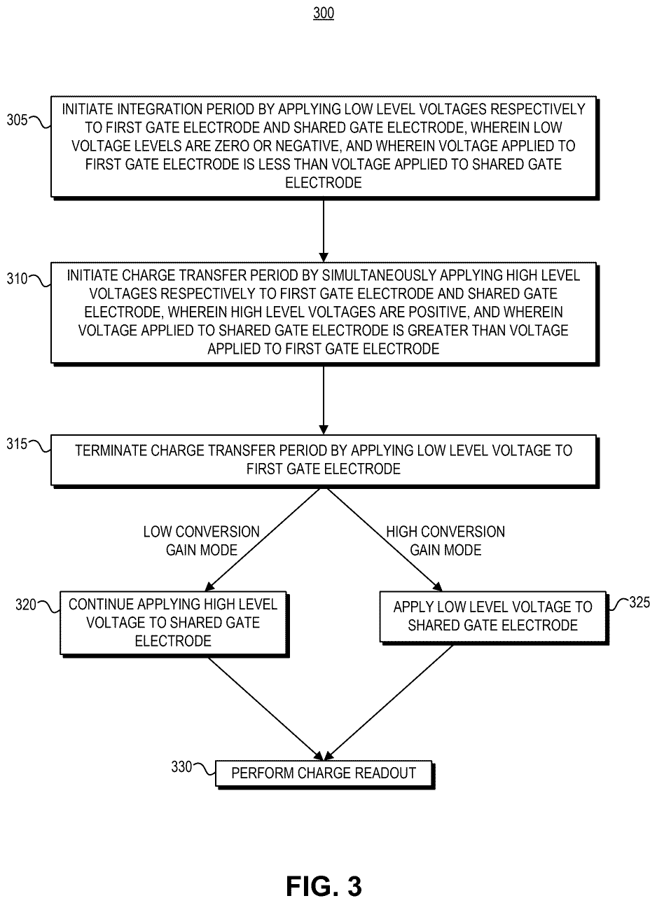

FIG. 3 illustrates a process 300 for operating a pixel cell (e.g., pixel cell 100 illustrated in FIG. 1A-1F or pixel cell 200 illustrated in FIG. 2A-2C) including a multi-gate transfer transistor (e.g., multi-gate transfer transistor 130 illustrated in FIG. 1D, multi-gate transfer transistor 230-1 illustrated in FIG. 2B-2C, or multi-gate transfer transistor 230-2 illustrated in FIG. 2B-2C), in accordance with an embodiment of the disclosure. The order in which some or all of the process blocks appear in process 300, which includes blocks 305, 310, 315, 320, 325, and 330 should not be deemed limiting. Rather, one of ordinary skill in the art having the benefit of the present disclosure will understand that some of the process blocks may be executed in a variety of orders not illustrated, or even in parallel.

Block 305 shows initiating an integration period for a first photodiode (e.g., first photodiode 105-1) of a pixel cell (e.g., pixel cell 100) by applying low level voltages respectively to a first gate electrode and a shared gate electrode (e.g., first gate electrode 110-1 and shared gate electrode 115) to accumulate (e.g., photogenerate) image charge in or near the first photodiode in response to incident light. In some embodiments, the low level voltages are negative. In the same or other embodiments, the voltage applied to the first gate electrode is less than the voltage applied to the shared gate electrode (e.g., low level voltage for first gate electrode corresponds to −1.4 V and low level voltage for shared gate electrode corresponds to −1 V to 0 V). In one embodiment, an example of process block 305 corresponds to time period 182 illustrated in FIG. 1E.

Block 310 illustrates initiating a charge transfer period by simultaneously applying high level voltages respectively to the first gate electrode and the shared gate electrode (e.g., first gate electrode 110-1 and shared gate electrode 115) to transfer the image charge from the first photodiode (e.g., first photodiode 105-1) to a floating diffusion (e.g., floating diffusion 120). In some embodiments, the high level voltages are positive. In the same or other embodiments, the voltage applied to the shared gate electrode (e.g., shared gate electrode 115) is greater than the voltage applied to the first gate electrode (e.g., high level voltage for first gate electrode corresponds to 2.8 V and high level voltage for shared gate electrode corresponds to 3.2 V).

Block 315 illustrates terminating the charge transfer period by applying the low level voltage to the first gate electrode (e.g., to electrically decoupled first photodiode 105-1 from floating diffusion 120).

Block 320 shows that during a low conversion gain mode of the pixel cell, the high level voltage is continued to be applied to the shared gate electrode. In one embodiment, an example of process block 310-320 corresponds to time period 184 illustrated in FIG. 1E.

Block 325 shows that during a high conversion gain mode of the pixel cell, a low level voltage is applied to the shared gate electrode (e.g., simultaneously or with a small timing delay relative to when the low level voltage is applied to the first gate electrode to terminate the charge transfer period). In one embodiment, an example of process block 310,315, and 325 corresponds to time period 183 illustrated in FIG. 1E.

Block 330 illustrates performing readout to obtain a signal voltage and subsequently generate an image signal representative of the image charge accumulated by the first photodiode. In one embodiment, an example of when to obtain (i.e., sample) the signal voltage during the low conversion gain mode corresponds to reference label 174 illustrated in FIG. 1E. In another embodiment, an example of when to obtain (i.e., sample) the signal voltage during the high conversion gain mode corresponds to reference label 173 illustrated in FIG. 1E.

FIG. 4 is a functional block diagram of an imaging system 400 including a pixel cell with a multi-gate transfer transistor (e.g., multi-gate transfer transistor 130 illustrated in FIG. 1D, multi-gate transfer transistor 230-1 illustrated in FIG. 2B-2C, or multi-gate transfer transistor 230-2 illustrated in FIG. 2B-2C), in accordance with an embodiment of the disclosure. In other words, imaging system 400 is one example of an associated image sensor or system having a pixel cell array of instances of pixel cell 100 illustrated in FIG. 1A-1F and/or pixel cell 200 illustrated in FIG. 2A-2C. Imaging system 400 includes photodiodes 405 configured to generate image charge in response to incident light 496 for imaging external scene 491, objective lens(es) 498 with adjustable optical power to focus on one or more points of interest within external scene 491, and controller 482 to control, inter alia, operation of imaging system 400. Imaging system 400 is a simplified schematic showing semiconductor substrate 401 with a plurality of photodiodes 405 disposed within respective portions of semiconductor substrate 401, a plurality of color filters 472, and a plurality of microlenses 476. Controller 482 includes one or more processors 484, memory 486, control circuitry 488, readout circuitry 490, and function logic 492.

Controller 482 includes logic and/or circuitry to control the operation (e.g., during pre-, post-, and in situ phases of image and/or video acquisition) of the various components of imaging system 400. Controller 482 can be implemented as hardware logic (e.g., application specific integrated circuits, field programmable gate arrays, system-on-chip, etc.), software/firmware logic executed on a general-purpose microcontroller or microprocessor, or a combination of both hardware and software/firmware logic. In one embodiment, controller 482 includes processor 484 coupled to memory 486 that stores instructions for execution by controller 482, processor 484, one or more other components of imaging system 400, or more generally imaging system 400. The instructions, when executed, can cause imaging system 400 to perform operations associated with the various functional modules, logic blocks, or circuitry of imaging system 400 including any one of, or a combination of, control circuitry 488, readout circuitry 490, function logic 492, components included in or on semiconductor substrate 401 such as plurality of photodiodes 405, objective lens 498, and/or any other element of imaging system 400 (illustrated or otherwise). Memory 486 is a non-transitory computer-readable medium that can include, without limitation, a volatile (e.g., RAM) or non-volatile (e.g., ROM) storage system readable by controller 482. It is further appreciated that controller 482 can be a monolithic integrated circuit, one or more discrete interconnected electrical components, or a combination thereof, which may be formed on one or more substrates that are coupled together. Additionally, in some embodiments one or more electrical components can be coupled together to collectively function as controller 482 for orchestrating operation of the imaging system 400.

Control circuitry 488 can control operational characteristics of the array formed by plurality of photodiodes 405 (e.g., exposure duration, when to capture digital images or videos, and the like). In some embodiments, control circuitry 488 corresponds to control circuit 140 illustrated in FIGS. 1B-1C. Readout circuitry 490 reads or otherwise samples the analog signal from individual photodiodes (e.g., read out electrical signals based on image charge generated by each of plurality of photodiodes 405 in response to incident light 496 to generate image signals for capturing an image frame representative of external scene 491, and the like) and can include amplification circuitry, analog-to-digital (ADC) circuitry, sample-and-hold circuitry, image buffers, or otherwise. In the illustrated embodiment, readout circuitry 490 is included in controller 482, but in other embodiments readout circuitry 490 can be separate from controller 482. Function logic 492 is coupled to readout circuitry 490 to receive image data to de-mosaic the image data and generate one or more image frames. In some embodiments, the electrical signals and/or image data can be manipulated or otherwise processed by function logic 492 (e.g., apply post image effects such as crop, rotate, remove red eye, adjust brightness, adjust contrast, or otherwise).

It is appreciated that embodiments of the disclosure illustrated in FIG. 1A-4 may be fabricated using conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is appreciated that the described techniques are merely demonstrative and not exhaustive and that other techniques may be utilized to fabricate one or more components of various embodiments of the disclosure.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A pixel cell for an image sensor, comprising:
a first photodiode, a second photodiode, and a floating diffusion, each disposed within a semiconductor material; and
a multi-gate transfer transistor configured to selectively couple the first photodiode and the second photodiode to the floating diffusion to transfer image charge from the first photodiode or the second photodiode to the floating diffusion, wherein the multi-gate transfer transistor includes:
a plurality of separated gate electrodes including a first gate electrode disposed proximate to the first photodiode, a second gate electrode disposed proximate to the second photodiode, and a shared gate electrode disposed proximate to the floating diffusion; and
an isolation structure disposed within the semiconductor material between the first photodiode and the second photodiode.

2. The pixel cell of claim 1, wherein the isolation structure is further disposed between the first gate electrode and the second gate electrode when the pixel cell is viewed from a plan view.

3. The pixel cell of claim 2, wherein the multi-gate transfer transistor further comprises a gate dielectric disposed between the semiconductor material and each of the first gate electrode, the second gate electrode, and the shared gate electrode, wherein the isolation structure includes a trench isolation structure and an isolation implant region aligned with the trench isolation structure, wherein the isolation implant region is oppositely doped relative to the first photodiode and the second photodiode, and wherein the isolation implant region is disposed between the trench isolation structure and the gate dielectric.

4. The pixel cell of claim 1, wherein the multi-gate transfer transistor further comprises:
a gate dielectric disposed between the semiconductor material and each of the first gate electrode, the second gate electrode, and the shared gate electrode; and
a doped channel region disposed within the semiconductor material proximate to the shared gate electrode, wherein the doped channel region extends from the floating diffusion towards the first photodiode or the second photodiode, wherein the doped channel region is separate from the first photodiode and the second photodiode, and wherein the doped channel region has a same conductivity type relative to the floating diffusion.

5. The pixel cell of claim 1, wherein the first gate electrode, the second gate electrode, and the shared gate electrode extend along a common lateral plane parallel to a first side of the semiconductor material.

6. The pixel cell of claim 1, wherein the shared gate electrode is disposed between the floating diffusion and the first gate electrode when the pixel cell is viewed from a plan view, wherein the shared gate electrode is further disposed between the floating diffusion and the second gate electrode when the pixel cell is viewed from the plan view.

7. The pixel cell of claim 1, further comprising:
a third photodiode and a fourth photodiode, each disposed within the semiconductor material; and
a second multi-gate transfer transistor configured to selectively couple the third photodiode and the fourth photodiode to the floating diffusion to transfer image charge from the third photodiode or the fourth photodiode to the floating diffusion, wherein the second multi-gate transfer transistor includes:
a plurality of second separated gate electrodes, including a third gate electrode disposed proximate to the third photodiode, a fourth gate electrode disposed proximate to the fourth gate electrode, and a second shared gate electrode disposed proximate to the floating diffusion.

8. The pixel cell of claim 7, wherein the floating diffusion is disposed between the shared gate electrode and the second shared gate electrode when the pixel cell is viewed from a plan view, wherein the shared gate electrode and the second shared gate electrode are each disposed between the first gate electrode and the third gate electrode, and wherein the shared gate electrode and the second shared gate electrode are each further disposed between the second gate electrode and the fourth gate electrode.

9. The pixel cell of claim 1, wherein a first longitudinal edge of the first gate electrode is parallel to a second longitudinal edge of the second gate electrode, and wherein a third longitudinal edge of the shared gate electrode is perpendicular to the first longitudinal edge of the first gate electrode and the second longitudinal edge of the second gate electrode, wherein a fourth longitudinal edge of the shared transfer gate is parallel to the third longitudinal edge, and wherein the fourth longitudinal edge is smaller than the third longitudinal edge.

10. The pixel cell of claim 1, wherein the first gate electrode and the second gate electrode at least partially enclose the shared gate electrode such that the shared gate electrode is respectively separated from the first photodiode and the second photodiode by the first gate electrode and the second gate electrode.

11. The pixel cell of claim 1, further comprising circuitry formed within a transistor region, wherein the floating diffusion is disposed between the shared gate electrode and the circuitry.

12. An image sensor, comprising:
a pixel cell included in a plurality of pixel cells arranged in rows and columns to form a pixel cell array, wherein the pixel cell includes:
a first photodiode, a second photodiode, and a floating diffusion, each disposed within a semiconductor material; and
a multi-gate transfer transistor configured to selectively couple the first photodiode and the second photodiode to the floating diffusion to transfer image charge from the first photodiode or the second photodiode to the floating diffusion, wherein the multi-gate transfer transistor includes:
a plurality of separated gate electrodes including a first gate electrode disposed proximate to the first photodiode, a second gate electrode disposed proximate to the second photodiode, and a shared gate electrode disposed proximate to the floating diffusion; and
a control circuit configured to control operation of the image sensor.

13. The image sensor of claim 12, wherein the control circuit is further configured to initiate a first charge transfer period for the first photodiode by simultaneously applying a first voltage to the first gate electrode and a second voltage to the shared gate electrode.

14. The image sensor of claim 13, wherein the first voltage and the second voltage are each positive, and wherein the second voltage applied to the shared gate electrode is greater than the first voltage applied to the first gate electrode during the first charge transfer period to form a potential gradient to facilitate image charge transfer from the first photodiode to the floating diffusion.

15. The image sensor of claim 13, wherein the control circuit is further configured to terminate the first charge transfer period for the first photodiode by transitioning the first voltage applied to the first gate electrode to a third voltage and further transitioning the second voltage applied to the shared gate electrode to a fourth voltage.

16. The image sensor of claim 15, wherein the third voltage is negative and the fourth voltage is negative or zero, and wherein the fourth voltage is greater than the third voltage.

17. The image sensor of claim 15, wherein the control circuit is further configured such that the transitioning the second voltage applied to the shared gate electrode to the fourth voltage occurs after the transitioning the first voltage applied to the first gate electrode to the third voltage.

18. The image sensor of claim 12, wherein during a high conversion gain readout operation for the pixel cell, voltage levels applied to the first gate electrode, the second gate electrode, and the shared gate electrode configured by the control circuit correspond to low level voltages.

19. The image sensor of claim 12, wherein during a low conversion gain readout operation for the pixel cell, voltage levels applied to the first gate electrode and the second gate electrode configured by the control circuitry correspond to low level voltages while a voltage level applied to the shared gate electrode corresponds to a high level voltage, and wherein the high level voltage is greater than the low level voltages.

20. The image sensor of claim 12, wherein the shared gate electrode of the multi-gate transfer transistor is configured to be biased at different voltage level to modulate a conversion gain of the pixel cell during readout, wherein separation between the shared gate electrode and both the first gate electrode and the second gate electrode provides isolation between the floating diffusion and both the first photodiode and the second photodiode.
